(19) United States
(12) Patent Application Publication
(10) Pub. No.: US 2016/0093800 A1
(43) Pub. Date: Mar. 31, 2016

(54) MEMORY DEVICE

(71) Applicant: Kabushiki Kaisha Toshiba, Minato-ku (JP)

(72) Inventor: Junya MATSUNAMI, Yokkaichi (JP)

(73) Assignee: Kabushiki Kaisha Toshiba, Minato-ku (JP)

(21) Appl. No.: 14/626,266

(22) Filed: Feb. 19, 2015

(30) Foreign Application Priority Data
Sep. 30, 2014 (JP) 2014-202635

(51) Int. Cl. H01L 45/00

(52) U.S. Cl. CPC H01L 45/08; H01L 45/1233; H01L 45/145; H01L 45/146; H01L 45/147; H01L 45/148; H01L 45/144; H01L 45/1608

(57) ABSTRACT

According to one embodiment, a memory device includes a first electrode and a second electrode. The memory device also includes a first variable resistance layer which is disposed between the first electrode and the second electrode. The memory device also includes a leakage current suppression layer which is disposed between the first electrode and the first variable resistance layer. The memory device also includes a second variable resistance layer which is disposed between the first electrode and the leakage current suppression layer. The memory device also includes a metal source layer which is disposed between the first electrode and the second variable resistance layer. In which metal oxide is contained in at least one of a boundary region in the first variable resistance layer to the leakage current suppression layer and a boundary region in the leakage current suppression layer to the first variable resistance layer.

### CROSS-REFERENCE TO RELATED APPLICATIONS

This application is based upon and claims the benefit of priority from Japanese Patent Application No. 2014-202635, filed on Sep. 30, 2014; the entire contents of which are incorporated herein by reference.

### FIELD

Embodiments described herein relate generally to a memory device.

### BACKGROUND

In recent years, there is an increasing need for integration of a semiconductor memory device. In order to meet this need, microfabrication of circuit patterns or memory cells of the semiconductor memory device has been progressing. In order to meet the need for microfabrication, there is a need for fine memory cells which operate as memory elements, in addition to improvement of accuracy of pattern forming.

A memory device using a metal source layer has been suggested. The memory device can hold data with a small area in a thin film and can be microfabricated.

### BRIEF DESCRIPTION OF THE DRAWINGS

FIG. 1 is a block diagram showing the configuration of a memory device according to a first embodiment;

FIG. 2 is a perspective view illustrating the memory device according to the first embodiment;

FIG. 3 is a schematic electrical configuration diagram of a memory cell array layer of the memory device according to the first embodiment;

FIG. 4 is a sectional view of the memory cell of the memory device according to the first embodiment;

FIGS. 5A to 5C are a schematic view illustrating a set operation and a reset operation of the memory cell of the memory device according to the first embodiment;

FIG. 6 is a schematic electrical configuration diagram of the memory cell array layer of the memory device in case of set operation according to the first embodiment;

FIG. 7 is a schematic view of an energy band of the memory cell of the memory device according to the first embodiment;

FIG. 8 is a diagram showing a relationship between an ion radius of a metal ion in metal oxide and an areal density of oxygen atoms in metal oxide; and

FIG. 9 is a flowchart of a method of manufacturing the memory device.

### DETAILED DESCRIPTION

According to one embodiment, a memory device includes a first electrode and a second electrode opposed to a part of the first electrode. The memory device also includes a first variable resistance layer which is disposed between the first electrode and the second electrode. The memory device also includes a leakage current suppression layer which is disposed between the first electrode and the first variable resistance layer, and is in contact with the first variable resistance layer. The memory device also includes a second variable resistance layer which is disposed between the first electrode and the leakage current suppression layer. The memory device also includes a metal source layer which is disposed between the first electrode and the second variable resistance layer. In which metal oxide is contained in at least one of a boundary region in the first variable resistance layer to the leakage current suppression layer and a boundary region in the leakage current suppression layer to the first variable resistance layer.

Hereinafter, embodiments of the invention will be described referring to the drawings.

In the following description, for convenience, a side close to a substrate side is referred to as a lower side.

### First Embodiment

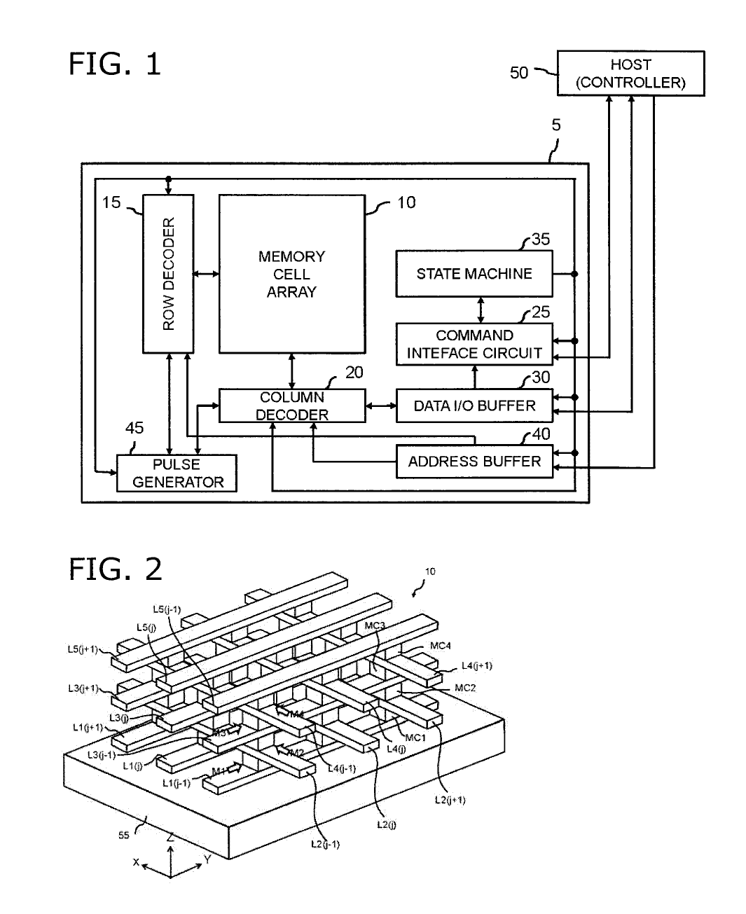

FIG. 1 is a block diagram showing the configuration of a memory device 5 according to a first embodiment.

As shown in FIG. 1, the memory device 5 includes a memory cell array 10, a row decoder 15, a column decoder 20, a command interface circuit 25, a data input/output buffer 30, a state machine 35, an address buffer 40, and a pulse generator 45.

The memory cell array 10 has a plurality of interconnects, and a plurality of other interconnects intersecting the interconnects in a stereoscopic manner. Memory cells are formed between the interconnects and other interconnects in the stereoscopic intersection portions.

The row decoder 15 is disposed at one end of the memory cell array 10, and the column decoder 20 is disposed at another end of the memory cell array 10.

The row decoder 15 selects, for example, a row of the memory cell array 10 based on a row address signal. The column decoder 20 selects a column of the memory cell array 10 based on a column address signal.

The command interface circuit 25 receives a control signal from a controller 50 (for example, a memory controller or a host). The data input/output buffer 30 receives data from the state machine 35.

The command interface circuit 25 determines whether or not data from the controller 50 is command data based on the control signal, and if data is command data, transfers data from the data input/output buffer 30 to the state machine 35.

The state machine 35 manages the operation of a variable resistance memory based on command data. For example, the state machine 35 manages a set/reset operation and a read operation based on command data from the controller 50. The state machine 35 also controls the row decoder 15, the column decoder 20, and the like.

The address buffer 40 receives an address signal from the controller 50 during the set/reset operation and the read operation. The address signal includes, for example, a memory cell array selection signal, a row address signal, and a column address signal. The address signal is input to the row decoder 15 and the column decoder 20 through the address buffer 40.

The pulse generator 45 outputs, for example, a voltage pulse or a current pulse necessary for the set/reset operation and the read operation at a predetermined timing based on a command from the state machine 35.

The controller 50 can receive status information which is managed by the state machine 35, and can determine an operation result in the variable resistance memory.

The controller 50 may be disposed in the memory device 5 or may be provided outside the memory device 5.

The basic configuration of the memory cell array 10 according to this embodiment will be described referring to FIG. 2. In this specification, for convenience of description, an XYZ orthogonal coordinate system is used. Two orthogonal directions parallel to an upper surface 55a of a substrate (for example, a silicon substrate) 55 are referred to as “X-direction” and “Y-direction”, and a direction perpendicular to the upper surface 55a is referred to as “Z direction”.

As shown in FIG. 2, the memory cell array 10 is disposed on the substrate 55. A circuit element, such as a MOS transistor, or a dielectric layer may be formed between the memory cell array 10 and the substrate 55.

FIG. 2 shows an example of a case where the memory cell array 10 has four memory cell array layers M1, M2, M3, and M4 stacked in the Z direction.

The memory cell array layer M1 includes memory cells MC1 disposed on an array in the X-direction and the Y-direction.

Similarly, the memory cell array layer M2 includes memory cells MC2 disposed on an array, the memory cell array layer M3 includes memory cells MC3 disposed on an array, and the memory cell array layer M4 includes memory cells MC4 disposed on an array.

In the following description, when there is no distinction among the memory cells MC1, MC2, MC3, and MC4, the memory cells are simply referred to as memory cells MC. A plurality of memory cells MC1 to MC4 are provided.

Conductive lines L1(j−1), L1(j), and L1(j+1), conductive lines L2(j−1), L2(j), and L2(j+1), conductive lines L3(j−1), L3(j), and L3(j+1), conductive lines L4(j−1), L4(j), and L4(j+1), and conductive lines L5(j−1), L5(j), and L5(j+1) are disposed on the substrate 55 in this order from the substrate 55. In the following description, when clear distinction is not required, the conductive lines are simply referred to as conductive lines L1, L2, L3, L4, and L5.

The odd-numbered conductive lines from the substrate 55, that is, the conductive lines L1, L3, and L5 extend in the Y-direction. The even-numbered conductive lines from the substrate 55, that is, the conductive lines L2 and L4 extend in the X-direction.

These conductive lines function as word lines or bit lines.

The lowest first memory cell array layer M1 is disposed between the first conductive line L1 and the second conductive line L2 from the substrate 55. In the set/reset operation and the read operation of the memory cell array layer M1, one of the conductive line L1 and the conductive line L2 is used as a word line, and the other conductive line is used as a bit line.

The same applies to the memory cell array layers M2 to M4.

That is, the memory cell array layer M2 is disposed between the second conductive line L2 and the third conductive line L3. One of the conductive line L2 and the conductive line L3 is used as a word line, and the other conductive line is used as a bit line.

The memory cell array layer M3 is disposed between the third conductive line L3 and the fourth conductive line L4. One of the conductive line L3 and the conductive line L4 is used as a word line, and the other conductive line is used as a bit line.

The memory cell array layer M4 is disposed between the fourth conductive line L4 and the fifth conductive line L5. One of the conductive line L4 and the conductive line L5 is used as a word line, and the other conductive line is used as a bit line.

In this embodiment, the conductive lines L1, L3, and L5 are referred to as word lines WL, and the conductive lines L2 and L4 are referred to as bit lines BL.

In the following description, when there is no distinction among the memory cell array layers M1, M2, M3, and M4, the memory cell array layers are simply referred to as the memory cell array layers M.

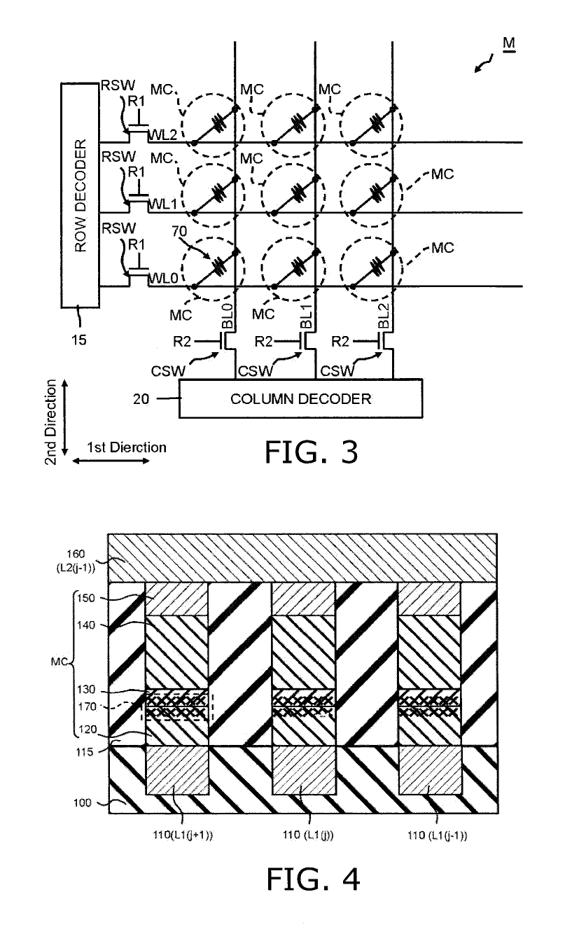

The basic configuration of a memory cell array layer M according to this embodiment will be described referring to FIG. 3. FIG. 3 is a schematic electrical configuration diagram of a part of the memory cell array layer M.

Each of memory cell array layers M shown in FIG. 2 includes (m+1)×(n+1) mats (not shown) disposed in a matrix. m and n are respectively a natural number not less than 1. Each of the mats includes a plurality of memory cells MC, and these memory cells are disposed in a matrix.

For example, 16 word lines WL and 16 bit lines BL are included in one mat. That is, (16×16) memory cells MC are included in one mat. Accordingly, the memory cell array layer M includes 16×(m+1) bit lines BL and 16×(n+1) word lines WL disposed in a matrix. The mats having the common word lines WL constitute units to be blocks BLK0 to BLKn. In the following description, when there is no distinction among the blocks BLK0 to BLKn, the blocks are simply referred to as blocks BLK.

Each of the memory cells MC includes a variable resistance element (resistance change element) 70. One end of a current paths of each variable resistance element 70 is connected to one of the bit lines BL0, BL1, BL2, . . . , and BL(16m+15), and the other end of the current path is connected to one of the word lines WL0, WL1, WL2, . . . , and WL(16n+15).

The row decoder 15 is electrically connected to one end of the word lines WL0, WL1, WL2, . . . , and WL(16n+15) through a switch element RSW. The switch element RSW includes an N-type FET which is controlled by a control signal R1.

The column decoder 20 is electrically connected to one end of the bit lines BL0, BL1, BL2, . . . , and BL(16m+15) through a switch element CSW. The switch element CSW includes, for example, an N-type FET which is controlled by a control signal R2.

The row decoder 15 and the column decoder 20 may write/erase/read data to one of a plurality of stacked memory cells or may write/erase/read data to two or more or all of a plurality of stacked memory cells.

In the following description, when there is no distinction among the word lines WL0, WL1, WL2, . . . , and WL(16n+15), the word lines are simply referred to as word lines WL. In the following description, when there is no distinction among the bit lines BL0, BL1, BL2, . . . , and BL(16m+15), the bit lines are simply referred to as bit lines BL.

Hereinafter, the configuration of a memory cell MC will be described with reference to FIG. 4. FIG. 4 is a sectional view of the memory cell array layer M1 and the memory cells MC1 formed between L1(j−1), L1(j), L1(j+1), and L2(j−1) in FIG. 2 when viewed from the Y-direction. The substrate side from the first inter-layer dielectric layer 100 and the side above the second conductive line L2(j−1) side will be omitted.

A first inter-layer dielectric layer 100 is formed on the substrate 55. For the first inter-layer dielectric layer 100, for example, SiO₂ is used.

Word line electrodes (second electrode) 110 for the conductive lines L1(j−1), L1(j), and L1(j+1) are formed above the first inter-layer dielectric layer 100. The memory cells MC are formed above the word line electrode 110. A bit line electrode (first electrode) 160 for the conductive line L2(j−1) is formed on the memory cells MC.

The memory cell MC includes a first variable resistance layer 120, a leakage current suppression layer 130, a second variable resistance layer 140, and a metal source layer 150 from the word line electrode 110.

A boundary region of the first variable resistance layer 120 and the leakage current suppression layer 130 contains metal oxide MOx. That is, at least a boundary region in the first variable resistance layer 120 to the leakage current suppression layer 130 or a boundary region 170 in the leakage current suppression layer 130 to the first variable resistance layer 120 contains metal oxide MOx. Metal oxide MOx may be contained in the interface region between the first variable resistance layer 120 and the leakage current suppression layer 130.

The word line electrodes 110 and the bit line electrode 160 include a metal layer and a barrier metal layer. For the metal layer, for example, tungsten is used. For the barrier metal layer, titanium, tantalum, titanium nitride, tantalum nitride, or a stack thereof is used.

The first variable resistance layer 120 and the second variable resistance layer 140 diffuse a metal ion 150a emitted from the metal source layer 150 inside thereof, thereby changing resistance values (described below).

An example of the first variable resistance layer 120 and the second variable resistance layer 140 is a layer containing silicon. For example, for the first variable resistance layer 120, silicon oxide is used. For the second variable resistance layer 140, silicon oxide, polycrystalline silicon, or the like is used. The first variable resistance layer 120 and the second variable resistance layer 140 may be a stacked body of silicon oxide and polycrystalline silicon.

The first variable resistance layer 120 and the second variable resistance layer 140 are not limited to such a layer containing silicon. An alloy of germanium, antimony, and tellurium, aluminum oxide, hafnium oxide, zirconium oxide, or the like may be used, or oxide of transition metal may be used.

For the leakage current suppression layer 130, a film having density of oxygen atoms smaller than the metal oxide MOx is used. For example, metal oxynitride, metal nitride, silicon oxide, silicon nitride, or silicon oxynitride, such as hafnium aluminum nitride, hafnium oxynitride, hafnium nitride, hafnium silicate (oxide containing hafnium and silicon), zirconium oxynitride, zirconium nitride, silicon oxide, silicon oxynitride, or silicon nitride, may be used.

For the metal oxide MOx, a material having high density of oxygen atoms, for example, aluminum oxide, titanium oxide, tantalum oxide, hafnium oxide, zirconium oxide, magnesium oxide, scandium oxide, or the like is used.

A more detailed combination of the first variable resistance layer 120, the leakage current suppression layer 130, and the metal oxide MOx will be described below.

For the metal source layer 150, for example, gold, silver, palladium, iridium, platinum, tungsten, hafnium, zirconium, titanium, nickel, cobalt, aluminum, chromium, copper, or the like may be used, and in the following description, silver is contained as an example.

Next, the operation of the memory cell MC will be described.

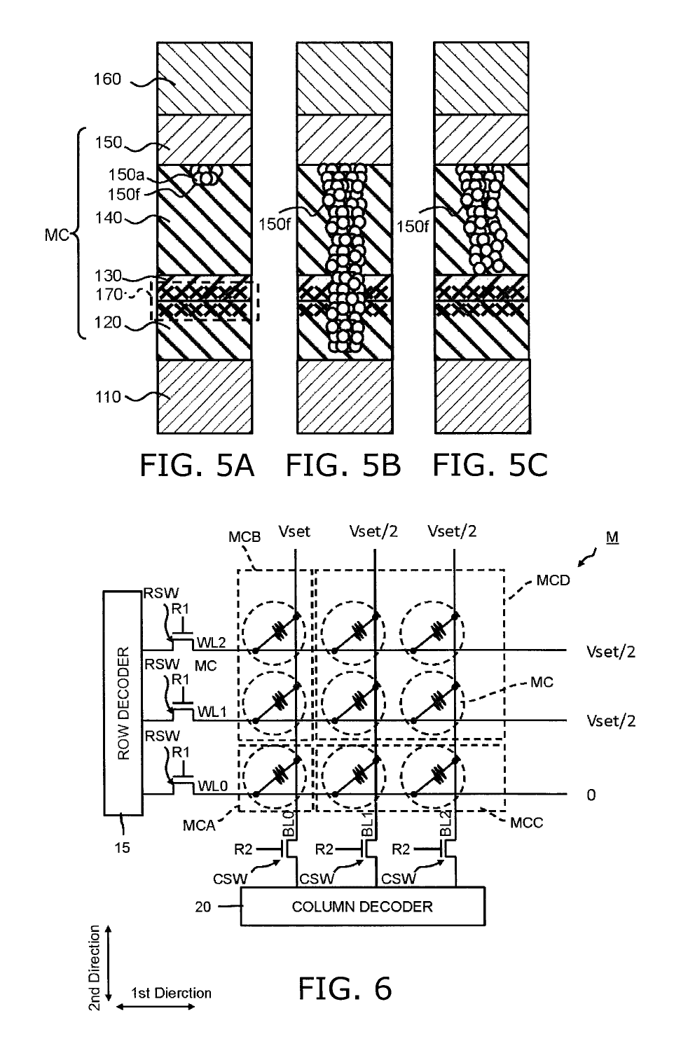

FIGS. 5A to 5C are schematic views illustrating the operation of a memory cell MC according to the first embodiment.

In FIGS. 5A to 5C, for simplification, only the memory cell MC portion, and the word line electrode 110 and the bit line electrode 160 immediately below and above the memory cell MC are shown.

FIG. 5A is a schematic view of a memory cell MC in a reset state “0”. In the reset state, a filament (metal filament) 150f formed using a silver ion 150a is absent, or even if a filament is present, the filament is accumulated immediately near the metal source layer 150.

First, a set operation will be described. A predetermined voltage is applied between the bit line electrode 160 and the word line electrode 110 for the memory cell MC in the reset state. A high potential is applied to the word line electrode 110 with respect to the bit line electrode 160. With the application of the voltage, the silver ion 150a is emitted from the metal source layer 150 to the second variable resistance layer 140, the leakage current suppression layer 130, and the first variable resistance layer 120. The emission of the silver ion 150a educes silver of the silver ion 150a, and as a result, the filament 150f extends.

The voltage continues to be applied, whereby the lower end of the filament 150f becomes close to or comes into contact with the word line electrode 110. This state is shown in FIG. 5B.

Therefore, if the voltage application is stopped, the filament 150f spontaneously shortens to the metal source layer 150 side. Even with the contraction, the filament 150f does not return to the reset state. However, it is desirable that the tip portion of the filament 150f on the word line side shortens above the leakage current suppression layer 130. This state is referred to as a set state “1”. The state of the memory cell MC in the set state is shown in FIG. 5C.

As described above, the memory cell MC is transited from the reset state “0” to the set state “1”, and data is written to the memory cell MC. This operation is referred to as a set operation. A voltage when the set operation is performed is referred to as a set voltage Vset, and a current flowing in the memory cell MC at the time of the application of the set voltage is referred to as a set current.

Next, in the memory cell state of FIG. 5C, a low voltage is applied to the bit line electrode 160 with respect to the word line electrode 110. With the application of the voltage, the silver ion 150a returns to the metal source layer 150, and the filament 150f is absent or if the filament is present, the filament is accumulated immediately near the metal source layer 150. This state of the memory cell MC is referred to as a reset state “0”. The state of the memory cell MC in the reset state is as shown in FIG. 5A.

With this, the resistance of the memory cell MC is transited from the set state “1” to the reset state “0”, and data written to the memory cell MC is erased. This data erase operation is referred to as a reset operation.

Next, a read operation in the set state “1” and the reset state “0” will be described

First, a read operation of the memory cell MC in the reset state “0” will be described.

A predetermined voltage lower than the set voltage Vset is applied between the bit line electrode 160 and the word line electrode 110. Since the applied voltage is lower than the set voltage, a sufficient electric field is not applied between the tip portion of the filament 150f and the word line electrode 110, the filament 150f does not sufficiently extend, the memory cell MC shows a high resistance state, and a current does not flow.

In contrast, in case of the memory cell MC in the set state “1”, before the application of the voltage, the filament 150f already comes below the second variable resistance layer 140.

Accordingly, if the predetermined voltage is applied, a sufficient electric field is applied between the tip portion of the filament 150f and the word line electrode 110, the filament 150f extends, and the filament 150f becomes close to or comes into contact with the word line electrode. That is, the memory cell MC shows a low resistance state, and current flows compared to the memory cell MC in the reset state.

In this way, it is possible to read the state of the memory cell by detecting the current flowing in the memory cell MC. This operation is referred to as a read operation. A voltage during the read operation is referred to as a read voltage.

In any case, if the application of the read voltage is stopped, the filament 150f spontaneously shortens to the metal source layer 150 side and approaches the state before the application of the voltage.

Next, a voltage relationship during write will be described referring to FIG. 6. Then, a leak current in an unselected cell during write will be described. Potentials to be applied are just an example, and a different potential application method may be applied.

FIG. 6 shows a voltage during a set operation to a memory cell MC connected to the word line WL0 and the bit line BL0.

In the following description, a memory cell MC which is subjected to the set operation is referred to a selected memory cell MC, and other memory cells MC are referred to as unselected memory cells MC. A word line and a bit line electrically connected to the selected memory cell MC are respectively referred to as a selected word line WL and a selected bit line BL, and other word lines and bit lines are respectively referred to as unselected word lines WL and unselected bit lines BL. A potential difference is positive when the bit line potential is larger than the word line potential, and is negative when the bit line potential is smaller than the word line potential.

Specifically, in FIG. 6, the word line WL0 is a selected word line WL, the word lines WL1 to WL(16n+15) are unselected word lines, the bit line BL0 is a selected bit line BL, and the bit lines BL1 to BL(16m+15) are unselected bit lines BL.

As shown in FIG. 6, the selected word line WL0 is applied with 0 V, and the unselected word lines WL1 to WL(16n+15) are applied with Vset/2. The selected bit line BL0 is applied with Vset, and the unselected bit lines BL1 to BL(16m+15) are applied with Vset/2. Vset is a set voltage during a set operation described below.

The selected memory cell MC connected to the selected word line WL0 and the selected bit line BL0, that is, a memory cell MC in a region MCA in FIG. 6 is applied with Vset. With the application of the voltage, the selected memory cell MC is in the set state.

A plurality of unselected memory cells MC are connected between the unselected word lines WL1 to WL(16n+15) and the selected bit line BL0. The unselected memory cells MC correspond to memory cells MC in a region MCB in FIG. 6. The unselected memory cells MC are applied with +Vset/2 as the potential difference between the unselected word lines WL and the selected bit line BL. With this, a leak current flows.

Similarly, a plurality of unselected memory cells MC are connected between the selected word line WL0 and the unselected bit lines BL1 to BL(16m+15). The unselected memory cells MC correspond to memory cells MC in a region MCC in FIG. 6. The unselected memory cells MC are applied with +Vset/2 as the potential difference between the selected word line WL and the unselected bit line BL. With this, a leak current flows.

Since the voltage Vset/2 to be applied is lower than the set voltage Vset, the filament 150f described above referring to FIGS. 5A to 5C will not come into contact with the word line electrode 110. However, in the set state, since the tip portion of the filament 150f reaches around the leakage current suppression layer 130, a leak current is likely to increase.

A plurality of unselected memory cells MC connected between the unselected word lines WL1 to WL(16n+15) and the unselected bit lines BL1 to BL(16m+15), that is, memory cells MC in a region MCD in FIG. 6 are applied with 0 V. That is, a leak current is not generated.

As described above, a case where a forward voltage is applied to the unselected memory cells MC and a leak current flows during the set operation has been described.

Since this leak current causes erroneous read or an increase in current consumption, in a large-scale memory cell array, it is desirable to suppress a leak current.

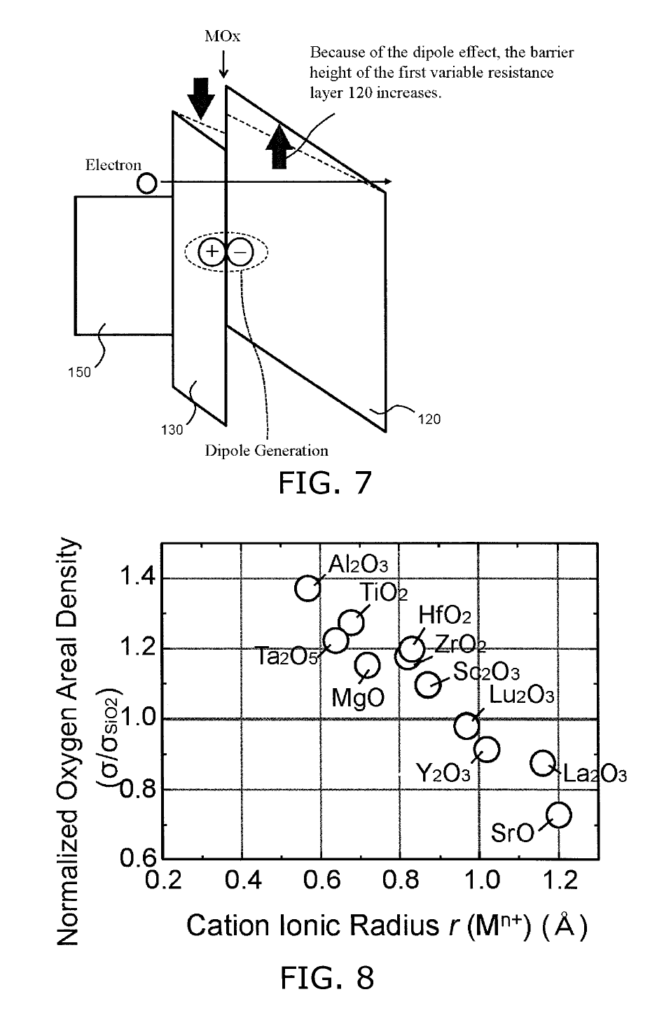

According to this embodiment, the metal oxide MOx is provided in the boundary region of the first variable resistance layer 120 and the leakage current suppression layer 130, whereby it is possible to reduce a leak current at the time of the application of a forward voltage. The details will be described referring to FIG. 7. FIG. 7 is a schematic view of an energy band of a memory cell MC. It is assumed that the tip portion of the filament 150f reaches the interface between the second variable resistance layer 140 and the leakage current suppression layer 130, and an electron is injected from the tip portion of the filament 150f. The second variable resistance layer 140 is omitted.

As described above, a leak current in this case is a current flowing between the filament 150f and the word line electrode 110. The second variable resistance layer 140, the leakage current suppression layer 130, and the first variable resistance layer 120 are present between the filament 150f and the word line electrode 110. If a voltage is applied between the bit line electrode and the word line electrode, a potential is applied to each layer. With the application of the potential, a tunnel current flows in each layer.

In this embodiment, the metal oxide MOx is provided in the boundary region of the leakage current suppression layer 130 and the first variable resistance layer 120. If the metal oxide MOx is different in density of oxygen atoms from a material in contact with the metal oxide MOx, oxygen moves in a direction of equalizing the density of oxygen atoms, an electric dipole (dipole) is generated. If the dipole is generated, a potential difference is generated.

Specifically, when the first variable resistance layer 120 contains oxygen, a dipole potential difference is generated due to the difference in density of oxygen atoms between the first variable resistance layer 120 and the metal oxide MOx. When the leakage current suppression layer 130 does not contain oxygen, a dipole potential difference is not generated between the oxygen atoms of the leakage current suppression layer 130 and the metal oxide MOx.

Because of the dipole potential difference, the height of the energy barrier of the first variable resistance layer 120 against the electron injected from the tip portion of the metal filament 150f increases, thereby suppressing tunneling of the electron and reducing a leak current.

As described above, in order to generate a dipole for reducing a leak current, it is necessary to appropriately combine the leakage current suppression layer 130, the first variable resistance layer 120, and the metal oxide MOx in the boundary region 170.

Specifically, it is preferable that the density of oxygen atoms in the metal oxide MOx is higher than the density of oxygen atom in the first variable resistance layer 120. It is desirable that the leakage current suppression layer 130 does not contain oxygen, or the oxygen density of the leakage current suppression layer 130 is lower than the oxygen density of the first variable resistance layer 120.

The density means, for example, areal density in a film. When areal density is unrecognizable, the density means the density of the number of atoms per unit volume.

Specific data of the density of oxygen atoms is as shown in FIG. 8. The horizontal axis of FIG. 8 represents the radius of a metal ion in metal oxide. The vertical axis of FIG. 8 represents areal density (normalized by the value of SiO₂) of oxygen atoms in metal oxide.

That is, the density of oxygen atoms has a relationship of Al₂O₃>TiO₂>Ta₂O₅>HfO₂>ZrO₂>MgO>Sc₂O₃>SiO₂ in a descending order. The density of oxygen atoms in oxynitride and nitride is made smaller than the density of oxygen atoms in metal oxide.

Hereinafter, a specific combination example will be described.

As a specific example, when silicon oxide is used for the first variable resistance layer 120, and aluminum oxide, titanium oxide, tantalum oxide, hafnium oxide, zirconium oxide, magnesium oxide, or scandium oxide is used for the metal oxide MOx, it is preferable that silicon oxynitride, silicon nitride, hafnium aluminum nitride, hafnium nitride, zirconium nitride, or the like is used for the leakage current suppression layer.

As another specific example, when hafnium oxide is used for the first variable resistance layer 120, and aluminum oxide or titanium oxide is used for the metal oxide MOx, it is preferable that hafnium aluminum nitride, hafnium oxynitride, hafnium nitride, hafnium silicate, zirconium oxynitride, zirconium nitride, silicon oxide, silicon oxynitride, silicon nitride, or the like is used for the leakage current suppression layer.

As a further specific example, when zirconium oxide is used for the first variable resistance layer 120, and aluminum oxide, titanium oxide, or the like is used for the metal oxide MOx, it is preferable that hafnium aluminum nitride, hafnium oxynitride, hafnium nitride, hafnium silicate, zirconium oxynitride, zirconium nitride, silicon oxide, silicon oxynitride, silicon nitride, or the like is used for the leakage current suppression layer.

In order to reduce a leak current using a dipole, it is desirable that the filament 150f does not enter the leakage current suppression layer 130 at the time of the application of the voltage +Vset/2.

Since the filament 150f is a conductor, a leak current flows in the shortest region of the filament 150f and the word line electrode 110. This is because, if the filament 150f passes through the leakage current suppression layer 130, a leak current flows without being affected by a dipole potential.

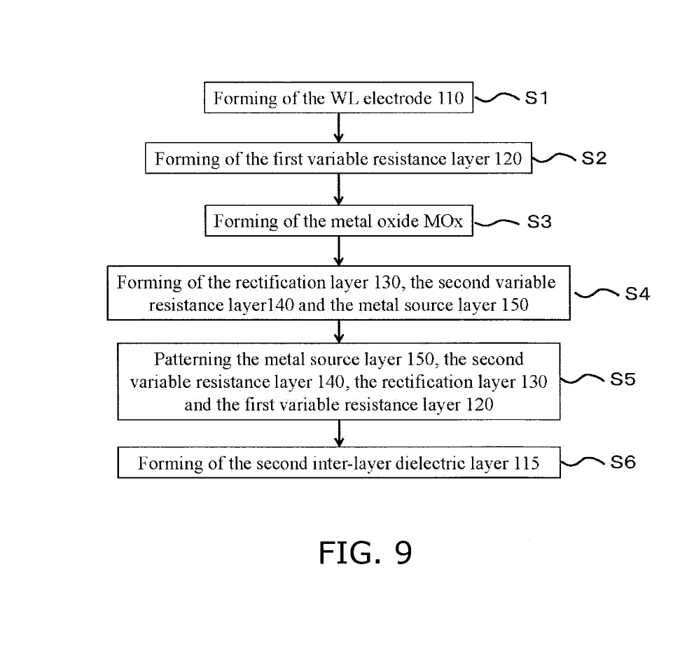

Next, a method of manufacturing a memory device according to this embodiment will be described. As an example, a flowchart of a method of manufacturing a memory cell array layer M1 is shown in FIG. 9.

First, the first inter-layer dielectric layer 100 is formed, and the word line electrode 110 is formed above the first inter-layer dielectric layer 100 (S1). For example, a predetermined mask pattern is formed on the first inter-layer dielectric layer 100 by a lithography method, and etching is performed by a reactive ion etching (RIE) method. A material for the word line electrode 110 is formed, and planarization is then performed by a chemical mechanical polishing (CMP) method.

Next, the first variable resistance layer 120 is formed (S2). A film forming method is, for example, a chemical vapor deposition (CVD) method, an atomic layer deposition (ALD) method, or the like.

The metal oxide MOx is formed on the first variable resistance layer 120 (S3). A film forming method is, for example a low-pressure CVD method, an ALD method, or the like. Typically, the metal oxide MOx is formed to have a thickness not more than 1 nm. In particular, when the thickness of the metal oxide MOx is not more than 1 molecular layer (ML), it is considered that the metal oxide MOx is not present as a film, and a dipole is formed in the interface between the first variable resistance layer 120 and the leakage current suppression layer 130.

Even if the thickness of the metal oxide MOx is several MLs, in a subsequent manufacturing process, the metal oxide MOx may be diffused, and the metal oxide MOx may not be present as a film. In this case, it is considered that the metal oxide MOx is not present as a film, and a dipole is formed.

Even when the thickness of the metal oxide MOx is not more than 1 ML or not more than several MLs, because of diffusion in a subsequent process, the metal oxide MOx is present in the boundary region in the first variable resistance layer 120 to the leakage current suppression layer 130 and the boundary region 170 in the leakage current suppression layer 130 to the first variable resistance layer 120.

Next, the leakage current suppression layer 130, the second variable resistance layer 140, and the metal source layer 150 are formed (S4). A film forming method is, for example, a physical vapor deposition (PVD) method, a CVD method, an ALD method, or the like.

A predetermined mask material is stacked on the metal source layer 150. A predetermined mask pattern is formed on the mask material by a lithography method, and the metal source layer 150, the second variable resistance layer 140, the leakage current suppression layer 130, and the first variable resistance layer 120 are etched by a reactive ion etching (RIE) method or the like (S5).

Thereafter, the second inter-layer dielectric layer 115 is formed (S6). Thereafter, planarization is performed by a chemical mechanical polishing (CMP) method.

Subsequently, various interconnect layers or circuit elements are formed using a method of manufacturing a general cross-point memory. In this way, the memory device 5 of this embodiment is manufactured.

In the memory device 5, the metal oxide MOx is provided in the boundary region in the first variable resistance layer 120 to the leakage current suppression layer 130 and the boundary region 170 in the leakage current suppression layer 130 to the first variable resistance layer 120. With this, a dipole is generated, and it is possible to reduce a leak current when a voltage is applied between a bit line and a word line.

In this way, in the first embodiment, the memory device 5 with small leak current and low current consumption is provided.

Hereinafter, modification and the like will be described.

Although the above description has been provided as to the memory cell array layer M1 as an example, the same applies to other memory cell array layers M.

For the odd-numbered memory cell array layers, that is, the memory cell array layers M1, M3, M5, . . . , the structure described referring to FIG. 4 may be used. For the even-numbered memory cell array layers, that is, the memory cell array layers M2, M4, M6, . . . , an inverted structure of the structure described referring to FIG. 4 is used. That is, the bit line electrode 160, the metal source layer 150, the second variable resistance layer 140, the leakage current suppression layer 130, the first variable resistance layer 120, and the word line electrode 110 may be formed in this order from the substrate side.

In the above description, although a case where Vset/2 is applied to the unselected word lines WL and the unselected bit lines BL has been described, the voltage to be applied may be smaller or greater than Vset/2 in a range not more than the voltage Vset. The unselected word lines WL and the unselected bit lines BL may be different in potential.

In the above description, although a cross-point memory has been described as an example, the invention may be applied to a memory device in which a word line electrode and a dielectric layer are stacked, a memory hole is formed in the stacked body, and a memory cell is formed inside the memory hole. That is, the invention is not limited to a cross-point memory in which the bit lines BL are parallel to the substrate 55, and may be applied to a memory device in which the bit lines BL are perpendicular to the substrate 55.

While the embodiments of the invention have been described, the embodiments are exemplary and are not intended to limit the scope of the invention. The embodiments can be embodied in various types in addition to the above-described embodiments, and various omissions, substitutions and modifications thereof can be made without departing from the gist of the invention. The embodiments and modifications thereof are included in the scope of the appended claims and equivalent ranges thereof, similarly as being included in the scope or gist of the invention.

What is claimed is:

1. A memory device comprising:
a first electrode;
a second electrode opposed to a part of the first electrode;
a first variable resistance layer which is disposed between the first electrode and the second electrode;
a leakage current suppression layer which is disposed between the first electrode and the first variable resistance layer, and is in contact with the first variable resistance layer;
a second variable resistance layer which is disposed between the first electrode and the leakage current suppression layer; and
a metal source layer which is disposed between the first electrode and the second variable resistance layer,
in which metal oxide is contained in at least one of a boundary region in the first variable resistance layer to the leakage current suppression layer and a boundary region in the leakage current suppression layer to the first variable resistance layer.

2. The memory device according to claim 1,
wherein the density of oxygen atoms in the metal oxide is higher than the density of oxygen atoms in the first variable resistance layer and the density of oxygen atoms in the leakage current suppression layer, and
the density of oxygen atoms in the first variable resistance layer is higher than the density of oxygen atoms in the leakage current suppression layer.

3. The memory device according to claim 1,
wherein the first variable resistance layer and the second variable resistance layer contain metal filaments which are made of metal diffused from the metal source layer, and
the metal filaments extend or shorten by a voltage applied between the first electrode and the second electrode.

4. The memory device according to claim 3,
wherein the metal filaments are formed only on the first electrode side from the leakage current suppression layer even when half of a voltage necessary to turn a memory element into low resistance state is applied.

5. The memory device according to claim 1,
wherein the first variable resistance layer contains silicon oxide,
the leakage current suppression layer contains at least one of silicon, hafnium, and zirconium and nitrogen, and
the metal oxide contains oxide of at least one metal element of aluminum, titanium, tantalum, hafnium, zirconium, magnesium, and scandium.

6. The memory device according to claim 1,
wherein the first variable resistance layer contains hafnium and oxygen,
the leakage current suppression layer contains at least one of hafnium aluminum nitride, hafnium oxynitride, hafnium nitride, hafnium silicate, zirconium oxynitride, zirconium nitride, silicon oxide, silicon oxynitride, and silicon nitride, and
the metal oxide contains oxide of at least one metal element of aluminum and titanium.

7. The memory device according to claim 1,
wherein the first variable resistance layer contains zirconium and oxygen,
the leakage current suppression layer contains at least one of hafnium aluminum nitride, hafnium oxynitride, hafnium nitride, hafnium silicate, zirconium oxynitride, zirconium nitride, silicon oxide, silicon oxynitride, and silicon nitride, and
the metal oxide contains oxide of at least metal element of aluminum and titanium.

8. The memory device according to claim 1,
wherein the metal source layer contains copper, silver, or a compound of copper and silver.

9. The memory device according to claim 1,
wherein the first variable resistance layer contains silicon.

10. The memory device according to claim 1,
wherein the first variable resistance layer contains an alloy of germanium, antimony, and tellurium.

11. The memory device according to claim 1,
wherein the metal source layer contains at least one metal selected from a group consisting of gold, palladium, iridium, platinum, tungsten, hafnium, zirconium, titanium, nickel, cobalt, aluminum, and chromium, or a compound of the selected metal.

12. The memory device according to claim 1,
wherein the thickness of the metal oxide is not more than 1 nm.

13. The memory device according to claim 3,
wherein the metal filaments are formed only on the first electrode side from leakage current suppression layer when half of a voltage necessary to turn a memory element into low resistance state is applied.

14. A memory device comprising:
a stacked body in which a dielectric layer and a first electrode are alternately stacked;
a memory hole which is formed to pass through the stacked body in the stacking direction of the dielectric layer and the first electrode;
a first variable resistance layer which is provided on the side surface of the memory hole;
a leakage current suppression layer which is provided on the side surface of the first variable resistance layer;
a second variable resistance layer which is provided on the side surface of the leakage current suppression layer;
a metal source layer which is provided on the side surface of the second variable resistance layer; and
a second electrode which is provided on the side surface of the metal source layer,
in which metal oxide is contained in at least one of a boundary region in the first variable resistance layer to the leakage current suppression layer and a boundary region in the leakage current suppression layer to the first variable resistance layer.

15. A method of manufacturing a memory device, the method comprising:
forming a first inter-layer dielectric layer on a substrate;
forming a second electrode above the first inter-layer dielectric layer;
forming a first variable resistance layer on the second electrode;
forming metal oxide on the first variable resistance layer;
forming a leakage current suppression layer, a second variable resistance layer, and a metal source layer in this order on the metal oxide;
selectively removing the metal source layer, the second variable resistance layer, the leakage current suppression layer, and the first variable resistance layer; and
depositing a dielectric film in the removed portion to form a second inter-layer dielectric layer.

16. The method according to claim 15,
wherein, in the metal oxide formation, the thickness of the metal oxide is not more than 1 nm.

17. A memory device comprising:
a first electrode;
a second electrode opposed to a part of the first electrode;
a first layer which is disposed between the first electrode and the second electrode;
a second layer which is disposed between the first electrode and the first layer, and is in contact with the first layer; and
a metal source layer which is disposed between the first electrode and the second layer,
in which metal element is contained in at least one of a boundary region in the first layer to the second layer and a boundary region in the second layer to the first layer.

18. The memory device according to claim 17, further comprising a third layer which is disposed between the metal source layer and the second layer.

19. The memory device according to claim 17,
wherein the first layer contains silicon oxide,
the second layer contains at least one of silicon, hafnium, and zirconium and nitrogen, and
the metal element contains at least one metal element of aluminum, titanium, tantalum, hafnium, zirconium, magnesium, and scandium.

20. The memory device according to claim 17,
wherein the first layer contains hafnium and oxygen,
the second layer contains at least one of hafnium aluminum nitride, hafnium oxynitride, hafnium nitride, hafnium silicate, zirconium oxynitride, zirconium nitride, silicon oxide, silicon oxynitride, and silicon nitride, and
the metal element contains at least one metal element of aluminum and titanium.
